(19) United States
(12) Patent Application Publication
(10) Pub. No.: US 2010/0297849 A1
(43) Pub. Date: Nov. 25, 2010

(54) PLASMA ETCHING METHOD FOR ETCHING AN OBJECT

(76) Inventors: Masatoshi Miyake, Kamakura-shi (JP); Nobuyuki Negishi, Tokyo (JP); Masatoshi Oyama, Kudamatsu-shi (JP); Tadamitsu Kanekiyo, Kudamatsu-shi (JP); Masaru Izawa, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/512,084

(22) Filed: Jul. 30, 2009

(30) Foreign Application Priority Data
May 22, 2009 (JP) 2009-124508

(51) Int. Cl. H01L 21/3065

(52) U.S. Cl. 438/710; 257/E21.218

(57) ABSTRACT

The invention provides a plasma etching method capable of suppressing bowing of an opening of the object to be etched, and solving the lack of opening at a high aspect ratio portion in deep hole processing having a high aspect ratio. A plasma etching method for etching an object to be etched in a plasma etching apparatus using a mask patterned and formed on the object to be etched comprises sequentially performing a first step for etching the mask while attaching deposits on a side wall of an opening close to a surface of the mask pattern of the mask using fluorocarbon gas CₓF_{y} (x=1, 2, 3, 4, 5, 6, y=4, 5, 6, 8), and a second step for etching the object to be etched while removing the deposits attached to the side wall of the opening close to the surface of the mask pattern of the mask using fluorocarbon gas.

The present application is based on and claims priority of Japanese patent application No. 2009-124508 filed on May 22, 2009, the entire contents of which are hereby incorporated by reference.

### BACKGROUND OF THE INVENTION

1. Field of the Invention

The present invention relates to a plasma etching method for etching an object using a plasma etching apparatus for manufacturing semiconductors.

2. Description of the Related Art

In the art of forming memories such as DRAMs, there are demands to perform ultrafine hole processing having an aspect ratio of 30 or greater with a hole diameter of 70 nm or smaller, so as to secure a sufficient electrostatic capacity in a small area. Further, the pitch of patterns have become narrower so as to ensure high level integration and minimum capacity, and therefore, it has become an important issue to suppress the occurrence of bowing and to improve the mask selective ratio when etching the object to be etched. Furthermore, important issues have become apparent such as the solving of deterioration of etch rate and the securing of bottom CD at a high aspect ratio portion of the object to be etched during etching.

For example, Japanese patent application laid-open publication No. 2007-158306 (patent document 1) discloses a method for etching an object, wherein an amorphous carbon film is formed on the surface of a patterned photoresist mask surface, by which the etching resistance of the photoresist surface is improved and the dimension of the opening portion is narrowed (shrunk).

On the other hand, Japanese patent application laid-open publication No. 2008-085092 (patent document 2) discloses a method for processing a semiconductor capable of suppressing the occurrence of an etch stop while securing the remaining film of a mask pattern by controlling the deposition rate of the deposition during the etching process for etching an object.

### SUMMARY OF THE INVENTION

The method disclosed in patent document 1 forms an amorphous carbon film on a photoresist prior to etching the object to be etched. According to this method, during the process of forming fine holes, there is fear that the deposition of the amorphous carbon film may close the opening of the mask pattern, so it was difficult to deposit a sufficient amount of amorphous carbon film. Further according to the method, when deep hole processing having a high aspect ratio is performed in a state where the amount of deposition of the amorphous carbon film is insufficient, the amorphous carbon film is removed via sputtering or the like at the initial stage of the etching process, and at the latter half of the etching process, sufficient etching resistance and shrinking effect of the mask may not be exerted.

The etching method disclosed in patent document 2 solves the tradeoff relationship between the mask selective ratio and etch stop, but it does not suppress bowing occurring during etching of a low or middle aspect ratio portion performed from the initial to the middle stages of etching by controlling the shape of the leading end portion of the mask. Further, the method focuses on the fact that etch stop does not occur easily while etching a high aspect ratio portion, and improves the mask selective ratio by increasing the deposition rate at the last stage of etching, but this method may further deteriorate the lowering of etching rate at the high aspect ratio portion.

The present invention aims at solving the problems of the prior art by providing a plasma etching method for etching an object so as to perform deep hole processing with a high aspect ratio using a plasma etching apparatus, capable of suppressing bowing occurring at the side wall of the opening of the object to be etched and solving the lack of opening at the bottom portion of the high aspect ratio portion.

The present invention aims at providing a plasma etching method for subjecting an object to be etched to ultrafine processing with a high aspect ratio, wherein during etching of a low or middle aspect ratio portion at the former half of the process for etching an object, deposits are attached to the side wall of the opening close to the surface of the mask while performing etching, and at the same time, a high mask selective ratio is realized, so as to prevent the occurrence of bowing of the object to be etched. Further according to the present invention, during etching of a high aspect ratio portion at the latter half the etching process, the deposits deposited on the side wall of the opening close to the mask surface is removed, and at the same time, ions having high directionality are entered so as to reduce the incident ions on the side wall causing bowing, thereby providing a plasma etching method capable of ensuring the bottom CD without causing increase of bowing of the object to be etched and deterioration of etch rate.

In order to solve the above-described problems, the present invention provides a plasma etching method for etching an object to be etched in a plasma etching apparatus using a mask having been patterned and formed on the object to be etched, comprising a first step for increasing the deposition rate and attaching deposits on the side wall of the opening close to the surface of the mask so as to narrow the opening, and a second step performed subsequently after the first step for reducing the deposition rate compared to the first step and etching the deposits deposited on the side wall of the opening close to the surface of the mask, according to which the deposits deposited on the side wall of the opening close to the surface of the mask for narrowing the opening in the first step are etched in the second step so as to reduce (remove) the deposits and to improve the directionality of ions being incident on the object to be etched.

The plasma etching apparatus to which the plasma etching method for etching an object according to the present invention is applied comprises a processing chamber, a gas supply means for supplying processing gas into the processing chamber, an evacuation means for depressurizing the processing chamber, an object mounting stage having an electrode on which the object to be processed is placed, an elevation mechanism for moving the object to be processed up and down, a high frequency power supply for generating plasma, and a direct expansion-type temperature control device for controlling the temperature of the electrode.

The present invention provides a plasma etching method for etching an object using a mask patterned and formed on the object to be etched, the method comprising attaching deposits on a side wall of an opening close to a surface of the patterned mask so as to narrow the opening, and forming a bowing on a side wall of the opening of the mask distanced from the surface of the mask for subjecting the object to plasma etching.

The present invention provides a plasma etching method for etching an object to be etched using a mask patterned and formed on the object to be etched in a plasma etching apparatus comprising a processing chamber, a gas supply means for supplying processing gas into the processing chamber, an evacuation means for depressurizing the processing chamber, and an object mounting stage for mounting the object to be etched, the method comprising sequentially performing a first step for forming deposits on a side wall of an opening close to the surface of the mask pattern of the mask so as to narrow the opening, and a second step for etching the deposits formed on the opening of the mask pattern of the mask and simultaneously etching the object to be etched.

According to the plasma etching method of the present invention, a processing pressure of the second step is set lower than that of the first step.

According to the plasma etching method of the present invention, a flow rate of the fluorocarbon gas CₓF_{y} (x=1, 2, 3, 4, 5, 6, y=4, 5, 6, 8) used in the first step and the second step is set smaller in the second step than in the first step.

According to the plasma etching method of the present invention, a C/F ratio of the fluorocarbon gas CₓF_{y} (x=1, 2, 3, 4, 5, 6, y=4, 5, 6, 8) used in the first step and the second step is set smaller in the second step than the fluorocarbon gas CₓF_{y} (x=1, 2, 3, 4, 5, 6, y=4, 5, 6, 8) used in the first step.

According to the plasma etching method of the present invention, a flow rate of O₂ gas used in the first step and the second step is set greater in the second step than in the first step.

According to the plasma etching method of the present invention, an electrode temperature for mounting the object to be etched is set higher in the second step than in the first step.

According to the plasma etching method of the present invention, the plasma etching apparatus is equipped with a direct expansion temperature control apparatus for controlling the temperature of the electrode for mounting the object to be etched.

According to the plasma etching method of the present invention, the processing conditions are changed either in three or more steps or continuously.

According to the plasma etching method of the present invention, a scatterometry is adopted for detecting an etching profile and performing feedback control, so as to control the etching profile stably for a long period of time.

The present invention provides a plasma etching method for etching an object to be etched using a mask patterned and formed on the object to be etched in a plasma etching apparatus comprising a processing chamber, a gas supply means for supplying processing gas into the processing chamber, an evacuation means for depressurizing the processing chamber, an object mounting stage for mounting the object to be processed, an elevation mechanism for moving the object to be processed up and down, and a high frequency power supply for generating plasma, wherein C₅F₆ gas having a cyclic structure is used as the etching gas.

The plasma etching method according to the present invention has high industrial applicability, since it enables to improve the yield in the process of manufacturing semiconductors.

### BRIEF DESCRIPTION OF THE DRAWINGS

FIG. 1 is a graph showing the relationship between mask taper angle θ and bowing/necking;

FIG. 2 is a graph showing the relationship between the aspect ratio (hole depth) per mask taper angle θ and the ion flux density being incident on the side wall of the hole;

FIG. 3 is a graph showing the relationship between the aspect ratio (hole depth) per mask leading end profile and the ion flux density being incident on the side wall of the hole;

FIG. 4A is a frame format illustrating the cross-sectional profile of a sample;

FIG. 4B is a frame format illustrating the cross-sectional profile of a state where the opening close to the surface of the mask is narrowed according to embodiment 1 of the present invention;

FIG. 4C is a frame format illustrating the cross-sectional profile of deep hole processing in which the object to be etched is etched using the mask illustrated in FIG. 4B;

FIG. 4D is a frame format illustrating the cross-sectional profile of a mask when etching of the object to be etched is performed midway using the mask illustrated in FIG. 4A according to the prior art method;

FIG. 4E is a frame format illustrating the cross-sectional profile of deep hole processing in which the object to be etched is etched using the mask illustrated in FIG. 4D according to the prior art method;

FIG. 5 is a graph showing the relationship between the aspect ratio (hole depth) per dispersion angle σ of incident ions being incident on the opening of the mask and the ion flux density being incident on the side wall of the hole;

FIG. 6 is a graph showing the relationship between the aspect ratio (hole depth) per dispersion angle σ of incident ions being incident on the opening of the mask and the ion incidence probability to the bottom of the hole;

FIG. 7 is a graph showing the relationship between the processing gas pressure and the deposition rate of CF polymer on the side wall of the hole;

FIG. 8-1A is a graph showing the prior art etching sequence;

FIG. 8-1B is a graph showing the step etching sequence for high aspect ratio processing according to the second embodiment of the present invention;

FIG. 8-2C is a graph showing the step etching sequence in which the steps are divided into three or more steps according to the second embodiment of the present invention;

FIG. 8-2D is a graph showing the step etching sequence in which the respective parameters are varied in a continuous manner according to the second embodiment of the present invention;

FIG. 9A is a frame format illustrating the cross-sectional profile of deep hole processing according to the second embodiment of the present invention;

FIG. 9B is a frame format illustrating the cross-sectional profile of deep hole processing according to the second embodiment of the present invention;

FIG. 9C is a frame format illustrating the cross-sectional profile of deep hole processing according to the second embodiment of the present invention;

FIG. 10 is a schematic view (cross-sectional view) showing an example of a structure of a plasma etching apparatus to which the plasma etching method according to the third embodiment of the present invention is applied; and

FIG. 11 is a structural formula of C₅F₆ gas having a cyclic structure.

### DETAILED DESCRIPTION OF THE PREFERRED EMBODIMENTS

When performing deep hole etching of an object to be etched using a mask, the bowing occurring at the upper portion of an opening (hole) of the object to be etched is increased by the ions and the like not introduced perpendicularly into the mask opening being reflected on the mask and being incident on the side walls of the opening of the object to be etched. Further, the shrinkage of processing dimension at the bottom of a hole having a high aspect ratio or the deterioration of etching rate are mainly caused by the reduction of ions reaching the bottom of the hole. The inventors of the present invention have discovered a method for suppressing the occurrence of bowing of the object to be etched by confining the negative effect of reflected ions to the mask portion disposed at the upper portion of the object to be etched. Further, the present inventors have discovered a method for increasing ions being directly incident on the bottom portion of the high aspect ratio hole portion without increasing ions being incident on the side walls of the hole, thereby solving the drawback in etching high aspect ratio portions. The following illustrates the embodiments of the plasma etching method for etching an object according to the present invention.

### Embodiment 1

In the present embodiment, a plasma etching method for etching an object using a patterned mask formed on the object to be etched will be described, comprising a first step of depositing deposits on a side wall of an opening close to an opening on the surface of the patterned mask during etching of the object to thereby narrow the opening and confine the occurrence of bowing to the side wall of the opening of the mask below the mask surface, and a second step of etching the object to be etched while etching the deposits deposited on the side wall of the opening close to the surface of the mask, thereby suppressing bowing of the side wall of the opening of the object to be etched.

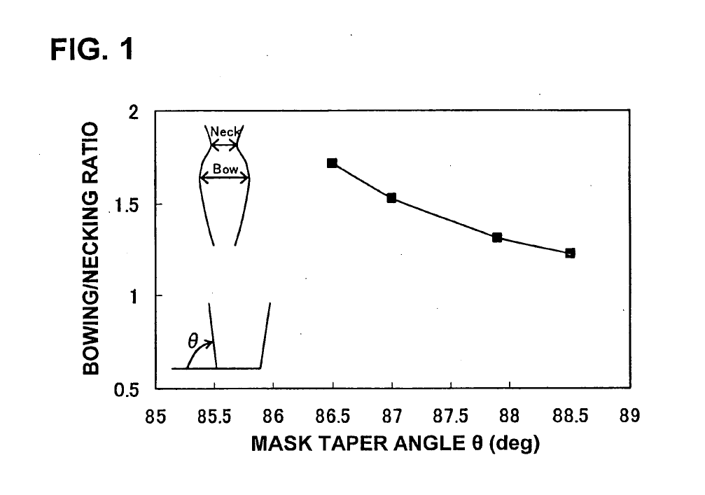

In the process of etching deep holes (high aspect ratio holes), when etching is performed under a condition in which the mask selective ratio (etching rate of object to be etched/etching rate of mask) is low, the leading end portion of the opening formed on the surface of the mask is gradually removed via sputtering, by which the leading end of the mask is widely opened in a tapered shape. When the opening near the surface of the mask is tapered, as illustrated in FIG. 1, the mask taper angle θ (rising angle at the bottom portion of the mask hole) becomes small, and the bowing/necking ratio (bowing) is undesirably increased. Even in a high aspect ratio hole, the bowing/necking ratio should preferably be 1.

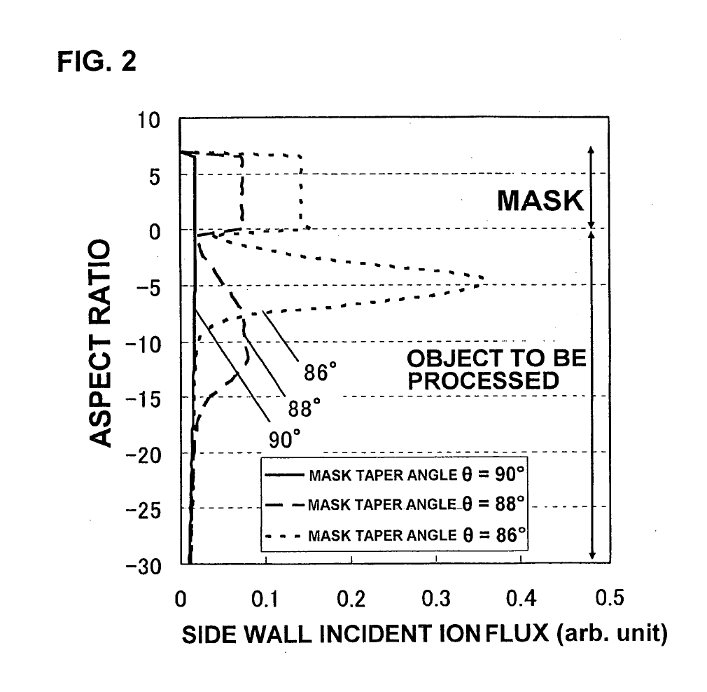

FIG. 2 illustrates a calculation result of ion incidence distribution to the side wall of an opening (hole) with respect to the aspect ratio (hole depth) per mask taper angle θ in the etching process. According to the calculation result, as the mask taper angle θ minimizes, the number of ions being incident on the side wall of the hole increases. When the mask taper angle θ is 90°, the ion density being incident on the side wall is substantially constant from the mask portion to the bottom portion of the object to be etched (SiO₂). However, when the mask taper angle θ is 88°, the ion density being incident on the side wall of the mask portion (aspect ratio=7 to 0) is greater compared to when the mask taper angle θ is 90°, and at the portion of the object to be etched (aspect ratio=0 to −30), it is increased approximately from aspect ratio −1 to aspect ratio −12, and substantially at aspect ratio −18, it becomes equivalent to the case where the taper angle is 90°. Similarly, when the mask taper angle θ is 86°, the ion density being incident on the side wall of the mask portion becomes even greater compared to when the mask taper angle θ is 90°, and at the portion of the object to be etched, it is increased approximately from aspect ratio −1 to aspect ratio −5, and substantially at aspect ratio −10, it becomes equivalent to the case where the taper angle is 90°. In other words, in deep hole etching, when the mask opening has a tapered shape in which the opening is opened toward the outer side, it is considered that bowing is increased by the ions being reflected by the mask being incident on the side wall of the hole, and therefore, it is recognized important to control the mask shape in order to suppress bowing.

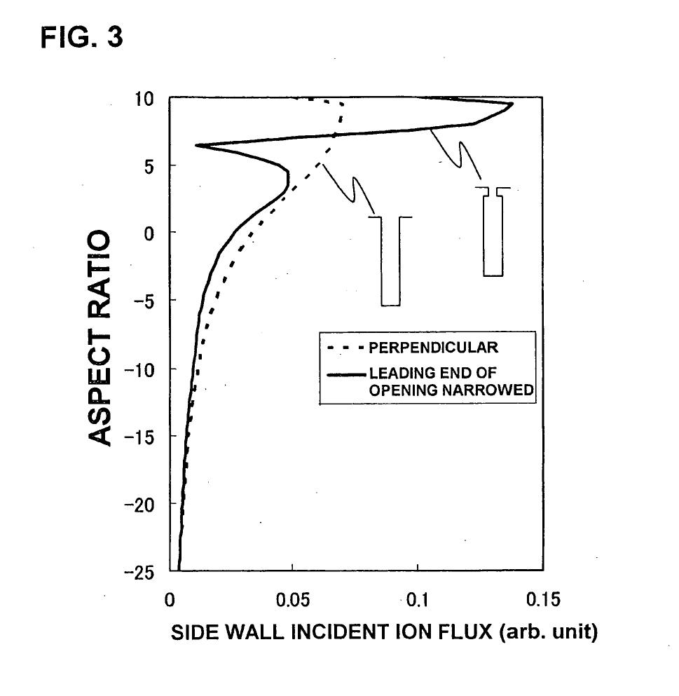

Next, we will illustrate in FIG. 3 the result of computing the ion incidence quantity to the side wall of the hole with respect to the aspect ratio (hole depth) when the shape of the opening portion (leading end portion) on the mask surface is varied. In FIG. 3, 0 represents the portion where the object to be etched and the mask come in contact with each other, the vertical axis (aspect ratio) shows the mask portion in the positive portion and the object to be etched in the negative portion, and the horizontal axis shows the ion density being incident on the side wall of the opening. From the computed results, it is recognized that even when the mask has a perpendicular (90°) mask taper angle θ as shown by the dotted line, if the incident angle of ions being incident on the opening of the mask has a certain dispersion, the ions become incident not only on the side wall of the opening of the mask but also the side wall of the opening (hole) of the object to be etched. In the actual etching, the ions being incident on the object to be etched are accelerated in the sheath region existing between the plasma and the object to be etched (object being processed), but the ions collide against neutral gases or the like in the acceleration region, by which the trajectory of the ions are varied, and the incident angle of ions becomes dispersed. On the other hand, when the opening close to the surface of the mask is reduced in size, as shown by the solid line, the incidence of ions are converged to the upper portion of the side wall of the opening (hole) close to the mask surface, and the ions being incident on the side wall of the hole at the portion of the object to be etched disposed below the mask are reduced. This is because when the opening near the mask surface is narrowed, the opening portion having been narrowed function as a hole having a high aspect ratio, so that the ions that are not perpendicular to the object to be etched repeatedly collide against the side wall (leading end portion) of the opening near the mask surface and lose their energy, minimizing the effect applied on the object to be etched disposed below the mask. In other words, if the opening near the mask surface is narrow, it functions as a filter with respect to the incident angle of incident ions, so that only the ions having a high perpendicularity contribute to the processing of the object to be etched, and therefore, the occurrence of bowing in the object to the etched can be suppressed.

Moreover, the increase of bowing (the portion of the upper portion of the object to be etched where the processing dimension is maximum) is caused not only by the ions reflected on the tapered mask or the dispersion of incidence angle, but also by the necking that occurs during deep hole etching. Necking is caused by deposition radicals transferred from the fluorocarbon plasma or the portion of the sputtered mask being deposited mainly on the upper portion of a hole. Similar to a tapered mask having an opened mask taper angle, the incident ions being reflected by the necking causes bowing to be formed directly below the necking. When the necking is formed near the surface of the mask at the upper portion of the hole, the bowing can also be confined within the mask. When the mask selective ratio of the etching rate is small, the progress of etching causes the generated positions of necking and bowing to move in the depth direction, so that when etching progresses, bowing occurs to the opening formed on the object to be etched. Therefore, in order to suppress the occurrence of bowing at the opening of the object to be etched, by maintaining a sufficiently long distance between the necking occurrence position at the opening of the mask to the object to be etched, the bowing can be formed within the mask, and by adopting a process of high mask selective ratio, it becomes possible to suppress the necking and bowing occurrence position from moving in the depth direction, thereby enabling to confine the bowing within the mask.

Now, an actual example of the method for narrowing the opening close to the surface of the mask will be described. First, the method for narrowing the opening close to the mask surface in deep hole etching will be described. The shape of the opening close to the mask surface is determined by the balance between the amount of chipping caused by sputtering due to ions being incident on the object to be processed or by chemical reaction and the deposition rate of deposition radicals within the plasma. Therefore, in order to narrow the opening close to the mask surface, it is necessary that CF (fluorocarbon) polymer which is a deposition radical deposits on a planar portion on the surface of the mask formed on the upper surface of the object to be etched at least in deep hole etching condition. When this condition is fulfilled, CF polymer deposits on the side wall of the opening close to the mask surface, and the opening can be narrowed. However, when the deposition rate of the CF polymer during etching of the object to be etched is too fast, the opening near the mask surface may become too narrow, undesirably closing the opening. In that case, either the deposition rate of the CF polymer during etching of the object to be etched is slowed down or the ion energy being incident on the mask opening is increased so as to enhance the effect of sputtering, to thereby prevent non-opening while narrowing the opening near the mask surface.

One actual method for increasing the deposition rate of the deposit for narrowing the opening near the mask surface is to utilize a high C/F ratio gas as the fluorocarbon gas CₓF_{y} (x=1, 2, 3, 4, 5, 6, y=4, 5, 6, 8) used for etching, so as to increase the amount of CF polymer being deposited. (Here, what is meant by a high C/F ratio is that the C/F ratio is greater than ⅔). As a result, simultaneously when narrowing the opening near the mask surface, CF polymers are deposited on the mask surface, so that the mask selective ratio in the etching of an object to be etched can be improved. Further, in order to obtain similar effects, by increasing the flow rate of fluorocarbon gas CₓF_{y} or by reducing the added amount of O₂ gas having an effect to remove CF polymer, the opening near the mask surface can be narrowed. Similar effects can be obtained by increasing the etching process pressure of the object to be etched or by lowering the temperature of the object to be etched. On the other hand, one possible method for solving the problem of the opening near the mask surface being closed is to increase the wafer bias power so as to increase the energy of incident ions, by which the effect of sputtering becomes enhanced and the closing of the opening near the mask surface can be suppressed.

Next, a method for forming the bowing within the mask so as not to affect the object to be etched will be described. Actually, similar to the example for narrowing the opening near the mask surface, by using a high C/F ratio gas as the fluorocarbon gas CₓF_{y} (x=1, 2, 3, 4, 5, 6, y=4, 5, 6, 8) used for etching the object to be etched, it becomes possible to realize a high mask selective ratio (etching rate of object to be etched/etching ratio of mask: in the description, what is meant by high or low selective ratio is that by varying the C/F ratio, the selective ratio becomes relatively high or low) during etching of the object to be etched. By realizing a high mask selective ratio, the reduction of mask during etching of the object to be etched is suppressed, and since the etching rate of the mask is slow, the generation of bowing is confined within the mask, and the bowing position can be confined to the leading end portion of the hole. Methods for increasing the mask selective ratio include increasing the fluorocarbon gas flow rate, increasing the etching pressure of the object to be etched, or lowering the temperature of the object to be etched, according to which similar effects can be obtained. Especially, when the opening close to the mask surface is narrowed, not only the occurrence of bowing of the object to be etched by the ion reflection within the mask opening caused by the tapered shape of the mask opening can be suppressed, but also the necking occurrence position can be set to the opening close to the mask surface, according to which the bowing occurrence position caused by necking can be formed within the opening near the mask surface (upper portion of the hole). As a result, the occurrence position of bowing can be confined within the mask disposed on the upper portion of the object to be etched. However, even by using an etching condition for realizing a high mask selective ratio, if the initial mask thickness is insufficient, bowing may still occur in the object to be etched. Therefore, the mask thickness is required to be sufficiently thick, and preferably, the aspect ratio of mask thickness with respect to the hole processing dimension should be 10 or greater, that is, the ratio of mask thickness/hole processing dimension should be 10 or greater.

The actual etching conditions of the present embodiment will now be described. At first, according to the prior art low-deposition etching conditions, a mixed gas of Ar/C₄F₆/O₂ is used as etching gas, and the Ar/C₄F₆/O₂=500/30/35 sccm. The processing pressure at this time is set to 2 Pa. Plasma is generated within a reaction apparatus by applying high frequency power via an antenna, and the plasma generating high frequency power at this time is 400 W. The bias power applied to a lower electrode is 5 kW, and the electrode temperature is set to +20° C.

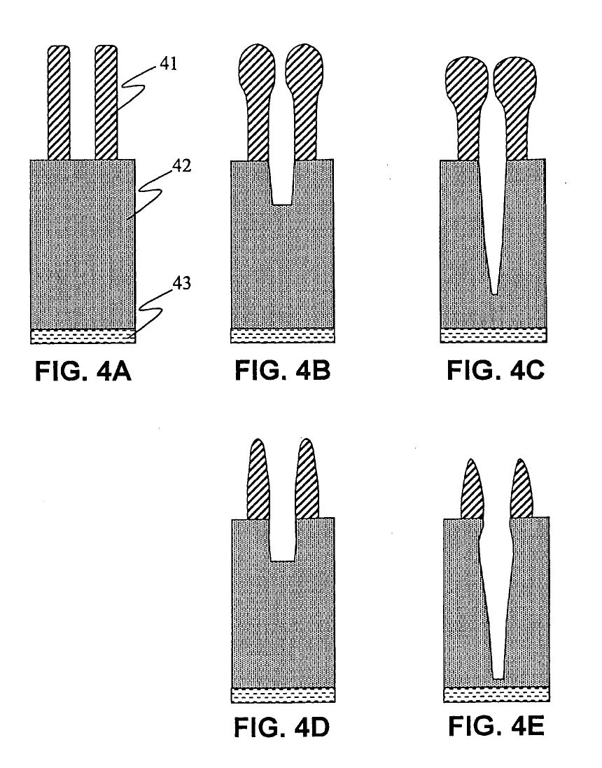

FIGS. 4A through 4E are used to describe the respective hole profiles of a case where the opening near the mask surface is narrowed and a normal case. FIG. 4A illustrates an initial profile of the evaluated sample. On a silicon oxide film (SiO₂) which is an object to be etched 42 being deposited on a silicon nitride film 43 as stopper layer of etching, a mask 41 composed of a patterned amorphous carbon film (ACL) is formed. A processed profiled formed via the prior art etching condition is shown in FIG. 4D. If the sputtering effect of ions being incident on the object to be processed is dominant with respect to the deposition rate via deposition radicals supplied from the plasma, the mask selective ratio is low, and the opening near the mask surface (leading end portion) is etched, by which the mask opening has a tapered shape opening toward the upper direction. Further, FIG. 4E illustrates the processing profile when the etching of the object to be etched is progressed. The mask is further reduced, and the tapered shape becomes further opened. Moreover, the ions reflected by the side wall of the opening of the tapered mask causes the bowing of the opening of the object to be etched to increase.

On the other hand, when performing the process under a high deposition etching condition according to the present invention, for example, the gas flow rate is doubled to Ar/C₄F₆/O₂=1000/60/70 sccm, and the process pressure is increased to 10 Pa. In this case, as shown in FIG. 4B, the mask is hardly reduced, and the opening near the mask surface can be narrowed. Further, by advancing the etching of the object to be etched, as shown in FIG. 4C, the opening with a high aspect ratio can be processed without expanding the bowing of the object to be etched.

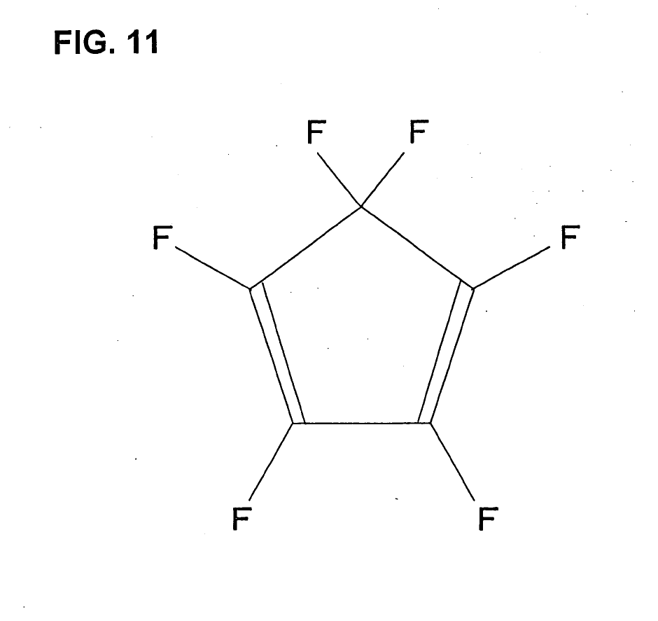

Further, the present embodiment illustrates a method for controlling the mask profile by using the same gas system and changing only the settings of the flow rate and process pressure. Further, a similar effect can be obtained by changing the etching gas of the object to be etched to a gas having a high C/F ratio. Especially, the use of a C₅F₆ gas having a cyclic structure shown in FIG. 11 is effective in increasing the deposition rate of CF polymer and realizing a high mask selective ratio. Further, one of the Fs constituting the C₅F₆ gas can be substituted by H. Further, a similar effect can be obtained by setting the set temperature of the electrode to a low temperature or by increasing the pressure of the helium gas pressure supplied between the electrode and the wafer so as to increase the cooling efficiency of the wafer.

As described, the first embodiment provides a plasma etching method for etching an object in a plasma etching device using a mask patterned and formed on the object to be etched, comprising a first step for attaching deposits on the side wall of the opening close to the surface of the patterned mask, and a second step for etching the object to be etched using the mask.

The first embodiment further provides a plasma etching method for etching an object in a plasma etching apparatus using a patterned mask formed on the object to be etched, comprising sequentially performing a first step for attaching deposits on the side wall of the opening close to the surface of the mask pattern of the mask using fluorocarbon gas CₓF_{y} (x=1, 2, 3, 4, 5, 6, y=4, 5, 6, 8), and a second step for etching the object to be etched while removing the deposits attached to the side wall of the opening close to the surface of the mask pattern of the mask using fluorocarbon gas CₓF_{y} (x=1, 2, 3, 4, 5, 6, y=4, 5, 6, 8).

### Embodiment 2

The present embodiment illustrates an etching method comprising sequentially performing a first step for etching an object to be etched by narrowing the opening close to the surface of the mask pattern by deposits, and a second step for etching the object to be etched while removing the deposits on the opening close to the surface of the mask pattern, thereby suppressing the shrinkage of processing dimension at the bottom portion of the hole and solving the deterioration of etch rate in a high aspect ratio.

Embodiment 1 illustrates a method for suppressing the occurrence of bowing in the object to be etched by narrowing the opening close to the surface of the mask. However, by narrowing the opening close to the surface of the mask, the efficient mask diameter is reduced, and the processing dimension of the bottom portion of the hole (bottom CD) may fall below the design value. Further, the incident ions have a certain dispersion angle by the collision with neutral gas or the like, but when the dispersion angle is large according to high gas pressure conditions or when performing etching with a high aspect ratio portion at the latter half of the etching process, many ions collide against the side wall of the hole before reaching the bottom, and the etch rate is deteriorated by the reduction of ions directly reaching the bottom of the hole.

If there is a drawback that the bottom dimension cannot be sufficiently ensured at the latter half of deep hole etching according to embodiment 1, in order to enlarge the processing dimension at the bottom portion of the hole (bottom), the bottom CD can be enlarged by performing a first step for narrowing the opening close to the surface of the mask by attaching deposits on the side wall of the opening, and a second step for removing the deposits on the opening close to the surface of the mask by etching the object to be etched. However, if the deposits on the opening of the mask is removed, the effect of removing ions having a large incident angle as illustrated in embodiment 1 is reduced, and bowing may occur on the side wall of the opening of the object to be etched. Therefore, according to the second step, by adopting a processing pressure lower than that of the first step, it becomes possible to enhance the directionality of the incident ions, by which the occurrence of bowing on the side wall of the opening of the object to be etched is suppressed and the deterioration of etching rate can be improved.

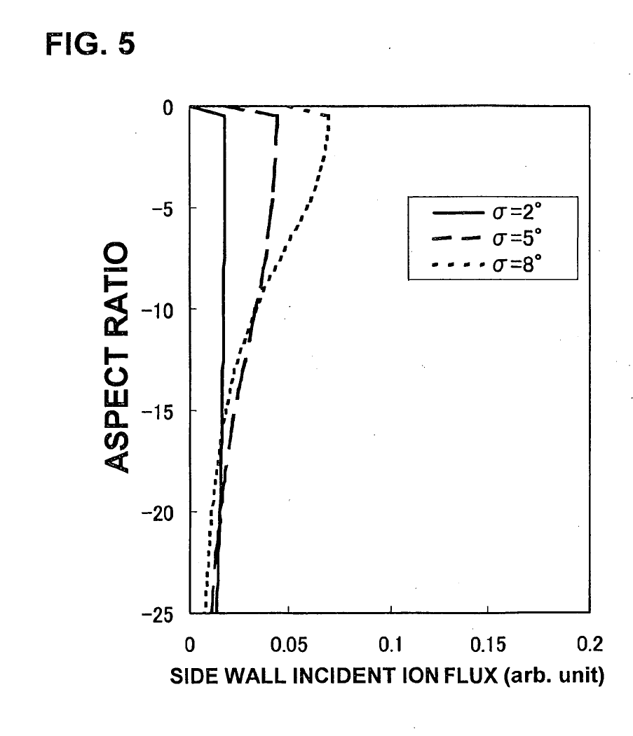

FIG. 5 illustrates the relationship between the ion flux being incident on the side wall of the hole with respect to the aspect ratio (hole depth) per angle of dispersion σ of incident ions. In FIG. 5, the aspect ratio on the vertical axis is shown as a depth of the opening from the mask surface when the dimension of the opening on the mask surface is constant. In the present example, aspect ratio −10 represents the boundary surface between the object to be etched and the mask. In the drawing, the case where the angle of dispersion σ of the incident ions is 2° is shown by the solid line, the case where the angle is 5° is shown by the broken line, and the case where the angle is 8° is shown by the dotted line. It can be recognized from this drawing that the smaller the angle of dispersion σ of ions, the less the ions being incident on the side wall of the opening close to the mask surface (side wall on the upper portion of the hole formed in the mask), so that the effect of suppressing bowing of the side wall of the opening of the object to be etched can be enhanced.

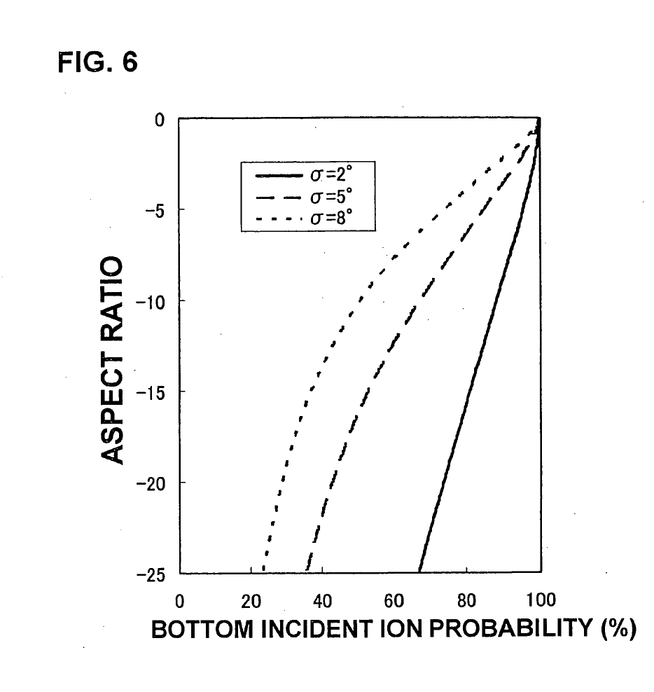

Further, FIG. 6 illustrates the ratio of the number of ions reaching the bottom of the hole directly with respect to the number of incident ions and the aspect ratio (hole depth) per angle of dispersion σ of incident ions. In FIG. 6, the aspect ratio on the vertical axis is illustrated as the depth of the opening from the mask surface when the dimension of the opening on the mask surface is constant. In the present example, aspect ratio −10 represents the boundary surface between the object to be etched and the mask. In the drawing, the case where the angle of dispersion σ of the incident ions is 2° is shown by the solid line, the case where the angle is 5° is shown by the broken line, and the case where the angle is 8° is shown by the dotted line. If the angle of dispersion σ of the incident ions is σ=8°, for example, when the aspect ratio (hole depth) is −10, more than a half of the incident ions will collide against the side wall of the hole before reaching the bottom of the hole. On the other hand, if the angle of dispersion σ is small (σ=2°), a large number of ions (approximately greater than 60%) will reach the bottom of the hole directly without colliding against the side wall of the hole (aspect ratio −25). The increase in the number of ions directly reaching the bottom of the hole leads to the increase of etching rate. Therefore, by improving the directionality of the ions, it is possible not only to suppress bowing but also to improve the deterioration of etching rate occurring at the high aspect ratio portion.

Now, the actual example for reducing the dimension of the leading end portion of the mask, that is, for widening the opening close to the mask surface will be described. The example illustrates a method for narrowing the opening close to the mask surface and simultaneously improving the directionality of the incident ions. Actually, by reducing the processing pressure in the second step for etching the object to be etched while removing the deposits deposited on the side wall of the opening close to the mask surface compared to the processing pressure in the first step for narrowing the opening close to the mask surface, it becomes possible to narrow the opening close to the mask surface and simultaneously increase the directionality of the ions.

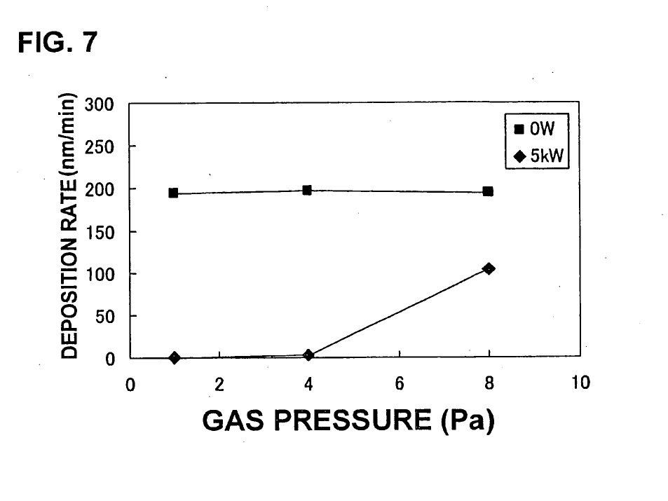

FIG. 7 shows the relationship between the processing pressure using fluorocarbon plasma, the deposition rate to the side wall of the hole, and the wafer bias. In the example, the gas flow rate is controlled so that the deposition rate becomes 200 nm/min when the wafer bias is 0 W. Under a gas flow rate condition in which the deposition rate becomes substantially constant when the wafer bias is 0 W, if the wafer bias is increased to 5 kW, the deposition rate is reduced. Especially when the processing pressure becomes lower, the deposition rate to the side wall of the hole is further reduced. Since the probability of ions being accelerated in the sheath region colliding against neutral gases and the like before reaching the object to be etched is reduced, high energy ions will be incident on the object to be etched, and the effect of ion sputtering is enhanced. As described, by reducing the processing pressure, the ion sputtering effect is enhanced, and the opening close to the mask surface can be narrowed. Further, the reduction of processing pressure reduces the probability of ions colliding against other gases and the like, by which the directionality of ions is improved, and the bowing of the side wall of the opening of the object to be etched can be suppressed. Moreover, since ions reaching the bottom of the hole directly are increased, the etch rate can be improved.

The present example illustrates a method for narrowing the opening close to the mask surface by reducing the processing pressure, but the deposition rate to the side wall of the hole can also be reduced by using a fluorocarbon gas having a lower C/F ratio as the fluorocarbon gas used in the second step with respect to the fluorocarbon gas used in the first step, or by reducing the fluorocarbon gas flow rate in the second step than in the first step, or by increasing the O₂ gas flow rate in the second step than in the first step, or by increasing the electrode temperature in the second step than in the first step. In the present embodiment, a direct expansion electrode disclosed in Japanese patent application laid-open publication Nos. 2008-034408 and 2008-034409 is adopted as a means for controlling the temperature of the electrode on which the object to be etched is placed, according to which a high speed control of approximately 1° C./s is realized. Further, the electrode is equipped with a heater capable of increasing the temperature. Moreover, similar effects can be expected by increasing the wafer bias and enhancing the effect of sputtering.

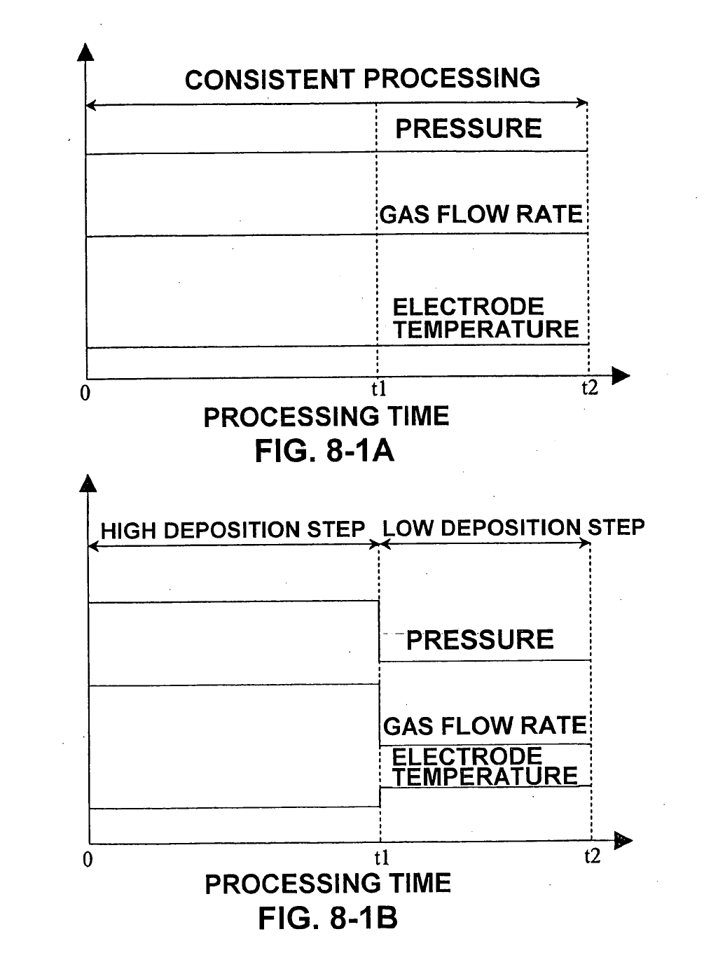

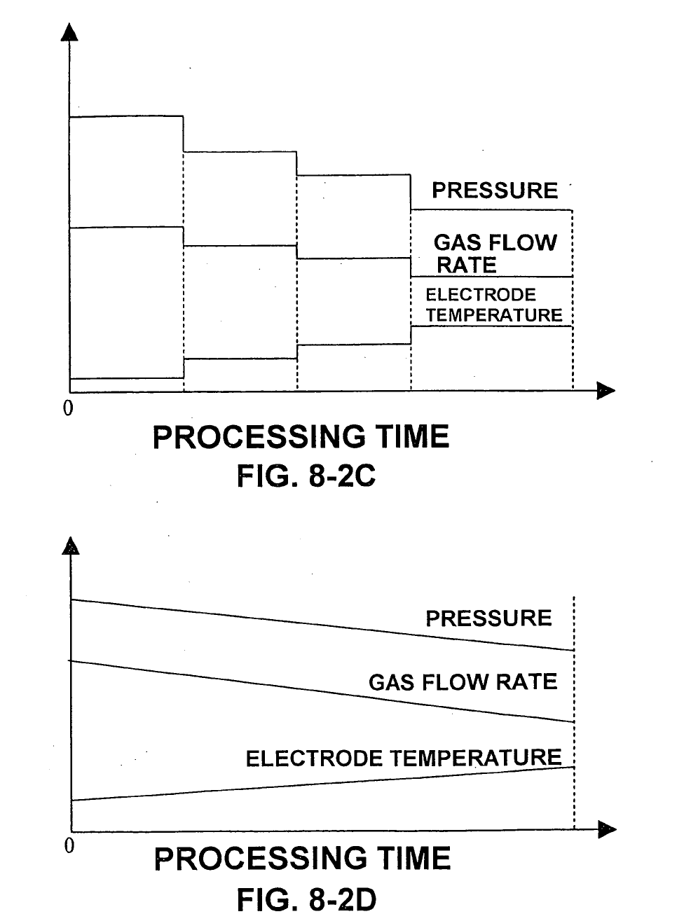

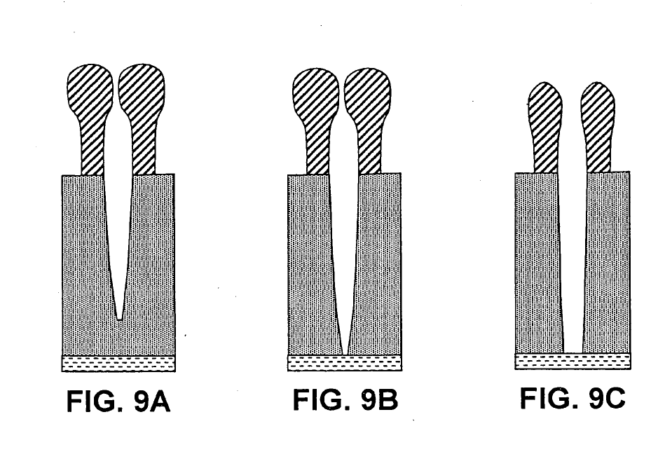

FIGS. 8-1A, 8-1B, 8-2C, 8-2D and FIGS. 9A, 9B and 9C are referred to in describing the etching sequence according to the present embodiment and the hole profile thereof. FIG. 8-1A illustrates the prior art etching sequence, and FIG. 8-1B illustrates the step etching sequence aimed at high aspect ratio processing. According to FIG. 8-1A illustrating the prior art sequence, consistent processing is performed without varying the etching conditions. For example, when the gas condition is set so that Ar/C₄F₆/O₂=1000/60/70 sccm and the processing pressure is set to 10 Pa, the etching profile at time t1 when etching of the object to be etched is performed under this condition is as shown in FIG. 9A. If etching is advanced without varying the processing conditions as illustrated in FIG. 8-1A, the opening dimension near the mask surface is too small, and the ions being incident in the hole is limited, so that at time t2, the opening dimension at the bottom is not sufficient, as shown in FIG. 9B. On the other hand, according to the step etching sequence illustrated in FIG. 8-1B, the processing pressure is reduced, the gas flow rate is reduced, and the electrode temperature is increased in the second step with respect to the first step. For example, when the processing pressure is set to 10 Pa in the first step, and the processing pressure is reduced to 2 Pa in the second step after time t1, as shown in FIG. 9C, the side wall of the opening close to the mask surface is removed via sputtering, and the directionality of the incident ions is increased, by which the bowing of the opening of the object to be etched can be suppressed while widening the processing dimension of the bottom of the hole.

According to the above embodiment, the mask profile and the directionality of incident ions were controlled merely by changing the setting of processing pressure, but the same effect of removing the deposits deposited on the side wall of the opening close to the mask surface can be obtained by changing the fluorocarbon gas to a gas having a lower C/F ratio in the second step with respect to the first step, and/or by raising the set temperature of the electrode, and/or by reducing the pressure of the helium gas supplied between the electrode and the wafer.

The above-illustrated embodiment was composed of two steps, a first step and a second step. However, as shown in FIG. 8-2C, it is possible to divide the number of steps into more than three steps, and by gradually reducing the processing pressure, increasing the gas flow rate and increasing the electrode temperature as the step advances, it becomes possible to control the profile of the opening formed on the object to be etched with higher accuracy. Further, the respective parameters can also be varied continuously as illustrated in FIG. 8-2D instead of varying them in a stepped manner.

### Embodiment 3

An etching method for controlling the etching profile stably for a long period of time with respect to the method for etching an object to be etched illustrated in embodiments 1 and 2 will now be described.

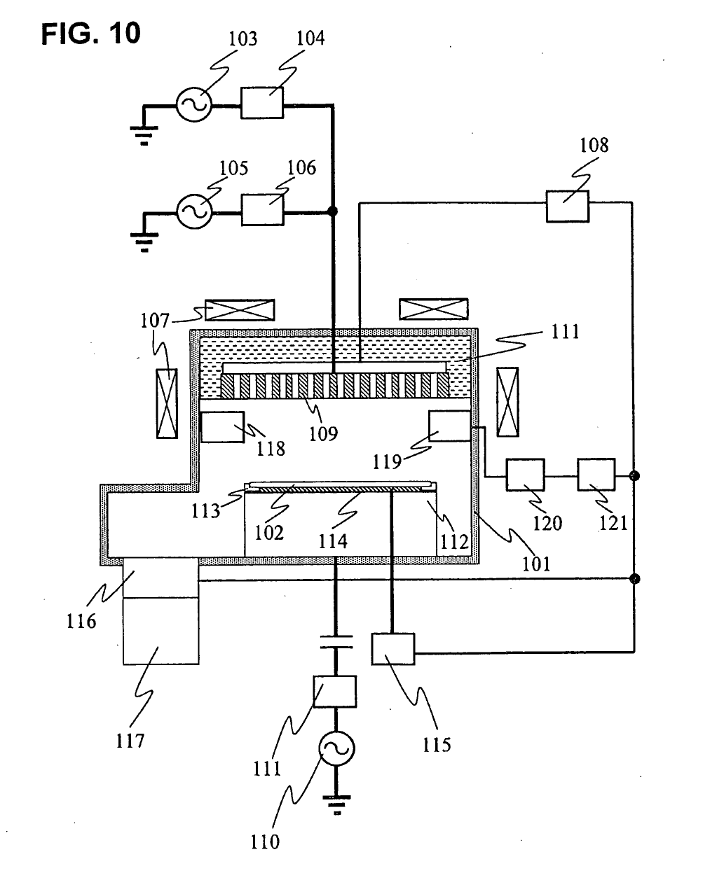

At first, the outline of the structure of a plasma etching apparatus for performing the plasma etching method according to the present invention will be illustrated in FIG. 10. The embodiment of FIG. 10 illustrates a basic structure of the plasma etching apparatus for realizing the present invention. The plasma etching apparatus comprises magnetic field coils 107 disposed on a vacuum reactor 101 having a gas introducing means 108 and an evacuation means 117, wherein the mutual reaction between the electromagnetic waves supplied through coaxial cables to the antenna 109 and the magnetic field generated by the magnetic field coils 107, the gas introduced to the vacuum reactor 101 is turned into plasma. At this time, by applying electromagnetic waves provided from a bias power supply 110 via a matching network 111 and a blocking capacitor to a sample mounting electrode 114, the object to be etched 102 can be subjected to high speed plasma processing. Two frequencies are applied to the antenna 109 according to the present embodiment, one from a first power supply 103 for generating plasma of 450 MHz via a first matching network 104 and another from a second power supply 105 of 4 MHz via a second matching network 106. The object to be processed 102 has a 12-inch diameter, and the distance between the object to be processed and the antenna 109 is 3 cm. The antenna 109 is formed of silicon, and material gas is introduced into the vacuum reactor 101 through multiple holes formed on the surface of the silicon. Further, in order to reduce the interior of the processing chamber to predetermined pressure, for example, an evacuation means 117 such as a turbo molecular pump and a gas pressure control valve 116 disposed before the evacuation means for adjusting the pressure of the processing chamber to predetermined pressure are provided. The electromagnetic waves from the second power supply 105 of 4 MHz have a function to control the potential formed between the surface of the antenna 109 and the plasma. By adjusting the output of the second power supply 105 of 4 MHz, the potential of the silicon surface can be adjusted arbitrarily, and the reaction between the antenna 109 and the active species within the plasma can be controlled. A stage 112 for placing the object to be etched (object to be processed) 102 is disposed in the processing chamber. The stage (mounting table) 112 has a sample mounting electrode 114 for attracting the object 102 to be processed, and pusher pins (not shown) for pushing up the object 102 to be processed. Further, a temperature control apparatus 115 is connected to the sample mounting electrode 114, by which the electrode temperature can be controlled.

Further, a scatterometry apparatus is disposed within the processing chamber. Scatterometry is, as disclosed in X. Niu, N. Jakatdar, IEEE Trans. on Semiconduct. Manufact., Vol. 14, pp 97-111, 2001 (non-patent document 1), a method of measuring the polarized state of reflected light by irradiating external light on the object to be processed, analyzing the obtained spectrum distribution based on a database, and computing the profile of the object to be processed.

According to the present invention illustrated in embodiments 1 and 2, it is important to control the mask profile in order to suppress bowing. By adopting scatterometry to obtain the etching profile, after performing etching, the etching profile can be computed using a scatterometry apparatus composed of an external light source 118, an emission monitor 119, and an apparatus 120 for analyzing emission. If there is a variation in the mask profile or the profile of the object to be etched, a control signal is sent to a feed back means 121 via a communication line, and the control signal is further sent via the communication line to the gas introducing means 108, the gas pressure control valve 116 and the temperature control device 115, by which the profile variation can be suppressed. For example, if the opening close to the mask surface is processed to a desired narrowed dimension, the fluorocarbon gas flow rate having an effect to increase the deposition rate of the CF polymer is increased via the feedback means, so as to narrow the opening near the mask surface. According to the present embodiment, the gas parameter subjected to feedback control is the fluorocarbon gas flow rate, but a similar effect can be obtained by reducing the O₂ flow rate having an effect to remove CF polymer. Furthermore, the profile can be stabilized by controlling the gas pressure control apparatus or the electrode temperature.

According to the above plasma etching apparatus, the profile was obtained via the scatterometry apparatus after performing etching, but it is also possible to obtain the profile via scatterometry while performing etching via in-situ monitoring, and by performing feedback for etching. Further according to the plasma etching apparatus, the scatterometry apparatus is attached to the processing chamber for measurement, but it can also be attached to a load lock chamber or an unload lock chamber. Further, it is possible to additionally dispose an independent scatterometry apparatus which is independent from the etching apparatus, so as to perform ex-situ monitoring. As described, by performing feedback based on the profile result obtained via the scatterometry apparatus, the profile can be controlled stably for a long period of time. Furthermore, similar effects can be obtained using a profile measuring means other than the scatterometry apparatus, if the means is capable of obtaining a profile measurement result equivalent to or more detailed than that obtained via the scatterometry apparatus.

According to the plasma etching apparatus described above, a method had been described in which the plasma is generated via the means for generating plasma applying a high frequency power different from that applied to the object to be processed to the electrode disposed facing the object to be etched, but similar effects can be obtained via a plasma etching apparatus characterized in generating plasma by a means applying high frequency power to the stage mounting the object to be etched, or by an inductively-coupled plasma generating means, or by the mutual interaction of magnetic field and high frequency electric field.

Further, the starting conditions according to the actual etching method described in the present embodiment are as follows: Ar/C₄F₆/O₂=1000/60/70 sccm; processing pressure of 10 Pa; set temperature of semiconductor wafer of 20° C.; and wafer bias of 5 kW. Similar effects can be obtained within the range in which the gas species, the gas flow rate, the pressure, the set temperature of wafer and the wafer bias are within a certain range from the above-disclosed conditions. Further, the present invention can also be applied to a process for etching a film having SiO₂, SiC, SiOC, SiOCH, SiN or Si₃N₄ as a main material disposed on a silicon substrate which is the object to be processed in a HARC etching process in which fluorocarbon-based gas is used as main component of the material gas of plasma. Further, the insulating film used for etching can be applied to etching a multilayered structure composed of two or more materials selected from SiO₂, SiC, SiOC, SiOCH, SiN and Si₃N₄ disposed on a silicon substrate being the object to be processed using the present plasma etching apparatus.

As described, the present embodiment enables to provide a plasma etching method capable of reducing bowing in deep hole processing with a high aspect ratio compared to prior art methods, and to overcome the shrinkage of processing dimension of the bottom of the hole and deterioration of etching rate of the high aspect ratio portion by performing plasma etching by varying etching conditions in association with the change of aspect ratio accompanying the progress of etching of the object to be etched.

What is claimed is:

1. A plasma etching method for etching an object to be etched in a plasma etching apparatus using a mask patterned and formed on the object to be etched, the method comprising:
etching the mask by attaching deposits on a side wall of an opening close to a surface of the patterned mask and forming a bowing on a side wall of the opening distant from the surface of the mask; and
etching the object to be etched using the mask.

2. A plasma etching method for etching an object to be etched in a plasma etching apparatus using a mask patterned and formed on the object to be etched, the method comprising:
sequentially performing a first step of etching the mask while attaching deposits on a side wall of an opening close to a surface of the mask pattern of the mask using fluorocarbon gas CₓF_{y} (x=1, 2, 3, 4, 5, 6, y=4, 5, 6, 8), and a second step of etching the object to be etched while removing the deposit attached to the side wall of the opening close to the surface of the mask pattern of the mask using fluorocarbon gas CₓF_{y} (x=1, 2, 3, 4, 5, 6, y=4, 5, 6, 8).

3. The plasma etching method for etching an object to be etched according to claim 2, wherein
a processing pressure of the second step performed subsequently after the first step is set lower than the processing pressure of the first step.

4. The plasma etching method for etching an object to be etched according to claim 2, wherein
a flow rate of the fluorocarbon gas CₓF_{y} (x=1, 2, 3, 4, 5, 6, y=4, 5, 6, 8) used in the first step and the second step is set smaller in the second step than in the first step.

5. The plasma etching method for etching an object to be etched according to claim 2, wherein
a C/F ratio of the fluorocarbon gas CₓF_{y} (x=1, 2, 3, 4, 5, 6, y=4, 5, 6, 8) used in the first step and the second step is set smaller in the second step than in the first step.

6. The plasma etching method for etching an object to be etched according to claim 2, wherein
a flow rate of O₂ gas added to the fluorocarbon used in the first step and the second step is set greater in the second step than in the first step.

7. The plasma etching method for etching an object to be etched according to claim 2, wherein
an electrode temperature for mounting the object to be etched is set higher in the second step than in the first step.

8. The plasma etching method for etching an object to be etched according to claim 7, wherein
the etching apparatus is equipped with a direct expansion temperature control apparatus for controlling the temperature of the electrode for mounting the object to be etched.

9. The plasma etching method for etching an object to be etched according to claim 2, wherein
the processing conditions according to the first step and the second step are varied either in three or more steps or continuously.

10. The plasma etching method for etching an object to be etched according to claim 1, wherein
scatterometry is adopted for detecting an etching profile and performing feedback control, so as to control the etching profile stably for a long period of time.

11. The plasma etching method for etching an object to be etched according to claim 2, wherein
scatterometry is adopted in detecting an etching profile and performing feedback control, so as to control the etching profile stably for a long period of time.

12. The plasma etching method for etching an object to be etched according to claim 3, wherein
scatterometry is adopted in detecting an etching profile and performing feedback control, so as to control the etching profile stably for a long period of time.

13. The plasma etching method for etching an object to be etched according to claim 1, wherein
C₅F₆ gas having a cyclic structure is used as the etching gas composed of fluorocarbon.

14. The plasma etching method for etching an object to be etched according to claim 2, wherein
C₅F₆ gas having a cyclic structure is used as the etching gas composed of fluorocarbon.
